(19) United States
(12) Patent Application Publication
(10) Pub. No.: US 2008/0205007 A1
(43) Pub. Date: Aug. 28, 2008

(54) ELEVATING DEVICE FOR LOADING ELECTRONIC EQUIPMENT THEREON

(76) Inventor: Arden Yang, Rosemead, CA (US)

Correspondence Address: CHRISTIE, PARKER & HALE, LLP, PO BOX 7068, PASADENA, CA, 91109-7068, US

(21) Appl. No.: 11/679,152

(22) Filed: Feb. 26, 2007

(51) Int. Cl. H05K 7/14

(52) U.S. Cl. 361/727; 361/725

(57) ABSTRACT

An elevating device is adapted for loading electronic equipment thereon, and includes a cover unit movable vertically on and covering a base. The cover unit cooperates with the base so as to define a volume-variable inner accommodating space therebetween. A driving mechanism is disposed in the inner accommodating space, and includes an extendable and retractable supporting unit mounted on the base for supporting the cover unit thereon, and a telescopic driving unit interconnecting the supporting unit and the base and operable so as to drive the supporting unit to extend and retract, thereby moving the cover unit to a desired position.

### BACKGROUND OF THE INVENTION

1. Field of the Invention

The invention relates to an elevating device, more particularly to an elevating device for loading electronic equipment thereon.

2. Description of the Related Art

For various-sized game machines, a small-sized game machine is usually placed on a loading frame, but a large-sized game machine is directly placed on the floor. As such, taller and shorter players cannot operate the fixed large-sized game machine at a comfortable posture.

### SUMMARY OF THE INVENTION

Therefore, the object of the present invention is to provide an elevating device for loading electronic equipment thereon that can position the electronic equipment at a desired height.

According to the present invention, an elevating device comprises:

a base;

a cover unit movable vertically on and covering the base, the cover unit cooperating with the base so as to define a volume-variable inner accommodating space therebetween; and

a driving mechanism disposed in the inner accommodating space and including

an extendable and retractable supporting unit mounted on the base for supporting the cover unit thereon, and

a telescopic driving unit interconnecting the supporting unit and the base and operable so as to drive the supporting unit to extend and retract, thereby moving the cover unit to a desired position.

### BRIEF DESCRIPTION OF THE DRAWINGS

Other features and advantages of the present invention will become apparent in the following detailed description of the preferred embodiment with reference to the accompanying drawings, of which:

FIG. 1 is a perspective view showing the preferred embodiment of an elevating device according to this invention when loading electronic equipment thereon;

FIG. 2 is a perspective view showing the preferred embodiment when an extendable and retractable supporting unit of the preferred embodiment is at an extended position;

FIG. 3 is a schematic sectional view showing the preferred embodiment; and

FIG. 4 is a block diagram illustrating a driving unit of the preferred embodiment.

### DETAILED DESCRIPTION OF THE PREFERRED EMBODIMENT

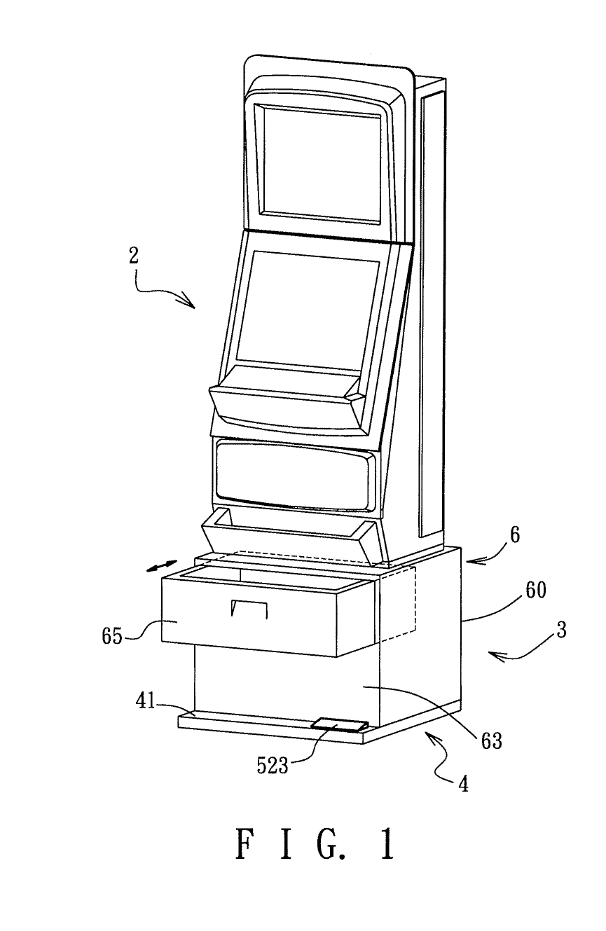

Referring to FIGS. 1 to 3, the preferred embodiment of an elevating device 3 according to the present invention is shown to include a base 4, a cover unit 6, and a driving mechanism 5. The elevating device 3 is adapted for loading electronic equipment, such as a large-sized game machine 2, thereon.

In this embodiment, the base 4 has a bottom wall 41, and a surrounding wall 42 connected integrally to a peripheral portion of the bottom wall 41.

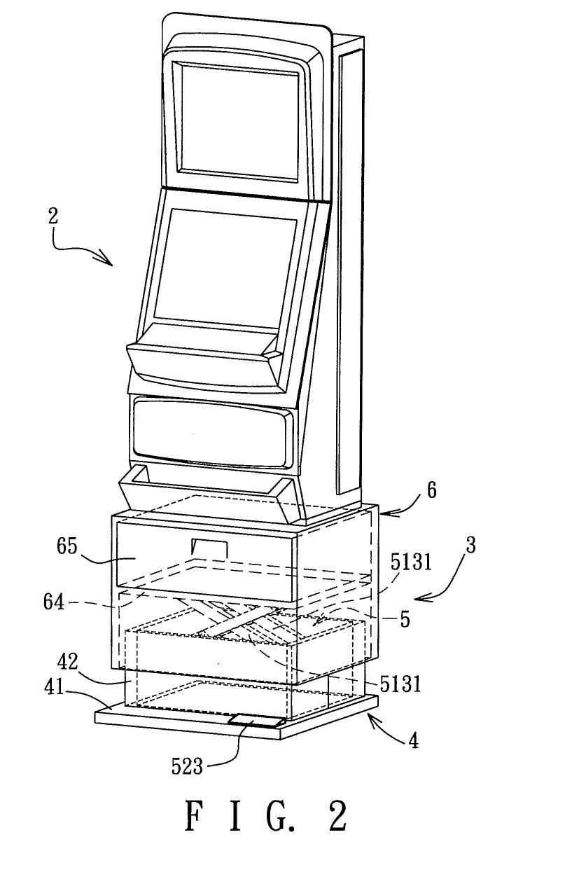

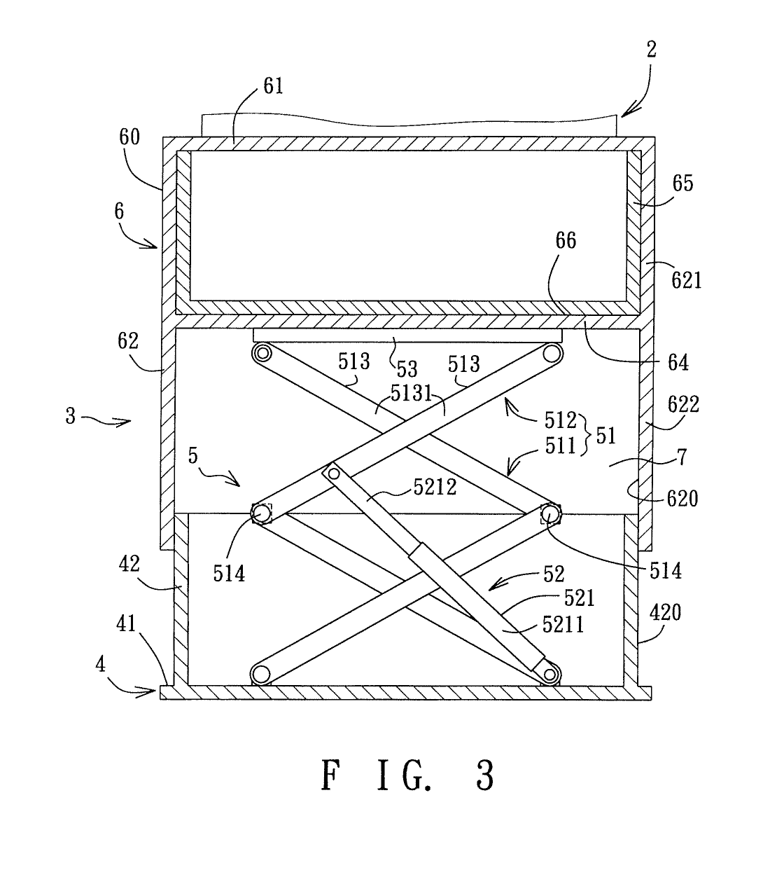

The cover unit 6 is movable vertically on and covers the base 4. The cover unit 6 cooperates with the base 4 so as to define a volume-variable inner accommodating space 7 therebetween. In this embodiment, as shown in FIG. 3, the cover unit 6 includes a cover body 60 having a front surface 63 formed with a drawer-receiving groove 66, and a drawer 65 disposed movably in the drawer-receiving groove 66 in the cover body 60. The cover body 60 has a top wall 61, a surrounding wall 62 connected integrally to a periphery of the top wall 61, and an inner wall 64 disposed parallel to and under the top wall 61 and having a periphery that is connected integrally to the surrounding wall 62. The top wall 61 cooperates with the inner wall 64 and an upper portion 621 of the surrounding wall 62 of the cover body 60 so as to define the drawer-receiving groove 66. The surrounding wall 62 of the cover body 60 has an annular inner surface 620 that is in slidable contact with an annular outer surface 420 of the surrounding wall 42 of the base 4. The bottom wall 41 and the surrounding wall 42 of the base 4 cooperate with the inner wall 64 and a lower portion 622 of the surrounding wall 62 of the cover body 60 so as to define the inner accommodating space 7. The driving mechanism 5 is disposed in the inner accommodating space 7, and includes an expendable and extractable supporting unit 51, a telescopic driving unit 52 and a carrying plate 53. The supporting unit 51 is mounted on the base 4 for supporting the cover unit 6 thereon. The carrying plate 53 is disposed between inner wall 64 of the cover body 60 and the supporting unit 51. In this embodiment, as shown in FIG. 3, the supporting unit 51 includes a pair of foldable link units 511, 512 each having upper and lower ends connected pivotally and respectively to the carrying plate 53 and the bottom wall 41 of the base 4. Each of the link units 511, 512 includes two link members 513 that are connected pivotally to each other by means of a pivot pin 514. Each of the link members 513 of one of the link units 511, 512 intersects a respective one of the link members 513 of the other one of the link units 511, 512 at a middle portion. Each link member 513 of each of the link units 511, 512 includes two parallel links 5131 that are interconnected by a respective one of the pivot pins 514 (see FIG. 2) so as to prevent relative rotation and movement therebetween.

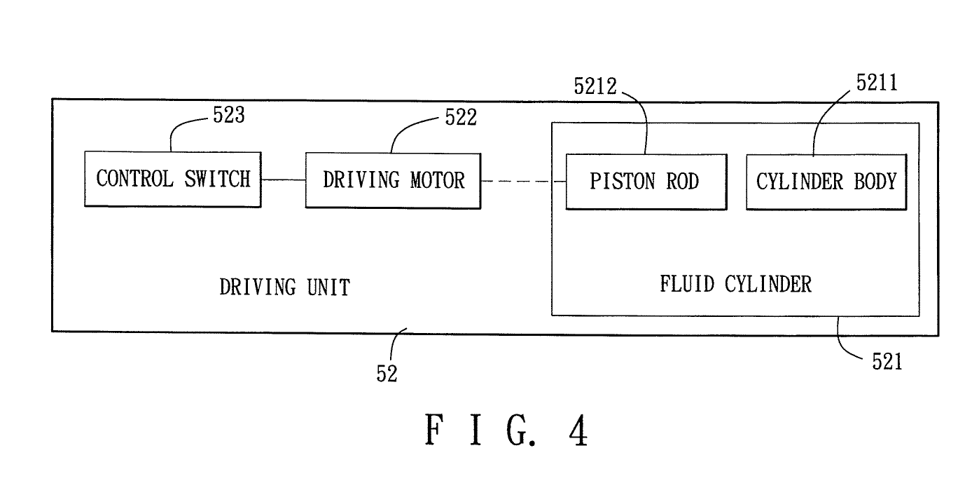

The driving unit 52 interconnects the supporting unit 51 and the base 4, and is operable so as to drive the supporting unit 51 to extend and retract, thereby moving the cover unit 6 to a desired position. In this embodiment, referring further to FIG. 4, the driving unit 52 includes a fluid cylinder 521, a control switch 523 and a driving motor 522. The fluid cylinder 521, such as a hydraulic cylinder, has a cylinder body 5211 connected pivotally to the bottom wall 41 of the base 4, and a piston rod 5121 coupled movably to the cylinder body 5211 and connected pivotally to an uppermost one of the link members 513 of the link unit 512 of the supporting unit 51. The control switch 523 is mounted on the bottom wall 41 of the base 4 (see FIG. 2), and is operable so as to output a control signal. The driving motor 522 is connected electrically to the control switch 523 for driving the piston rod 5212 based on the control signal from the control switch 523 to move and position the supporting unit 51 to the desired position.

In actual use, the elevating device 3 of this invention can position the game machine 2 supported thereby at a desired height suitable for a player through control for extension and retraction of the supporting unit 51 by the control switch 523. Furthermore, due to the presence of the drawer 65, the elevating device 3 of this invention can provide an additional accommodating space, thereby resulting in added convenience during use.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

We claim:

1. An elevating device comprising:
a base;
a cover unit movable vertically on and covering said base, said cover unit cooperating with said base so as to define a volume-variable inner accommodating space therebetween; and
a driving mechanism disposed in said inner accommodating space and including
an extendable and retractable supporting unit mounted on said base for supporting said cover unit thereon, and
a telescopic driving unit interconnecting said supporting unit and said base and operable so as to drive said supporting unit to extend and retract, thereby moving said cover unit to a desired position.

2. The elevating device as claimed in claim 1, wherein said driving mechanism further includes a carrying plate disposed between said cover unit and said supporting unit.

6. The elevating device as claimed in claim 2, wherein:
said supporting unit of said driving mechanism includes a pair of foldable link units each having upper and lower ends connected pivotally and respectively to said carrying plate and said base, each of said link units including a plurality of link members, any two adjacent ones of which are connected pivotally to each other, each of said link members of one of said link units intersecting a respective one of said link members of the other one of said link units at a middle portion thereof; and
said driving unit of said supporting mechanism includes
a fluid cylinder having a cylinder body connected pivotally to said base, and a piston rod coupled movably to said cylinder body and connected pivotally to an uppermost one of said link members of one of said link units of said supporting unit,
a control switch mounted on said base and operable so as to output a control signal, and
a driving motor connected electrically to said control switch for driving said piston rod based on the control signal from said control switch to move and position said supporting unit to the desired position.

4. The elevating device as claimed in claim 2, wherein said supporting unit of said driving mechanism includes a pair of foldable link units each having upper and lower ends connected pivotally and respectively to said carrying plate and said base, each of said link units including a plurality of link members, any two adjacent ones of which are connected pivotally to each other, each of said link members of one of said link units intersecting a respective one of said link members of the other one of said link units at a middle portion thereof.

5. The elevating device as claimed in claim 4, wherein each of said link members of each of said link units includes two parallel links that are interconnected so as to prevent relative rotation and movement therebetween.

6. The elevating device as claimed in claim 1, wherein said driving unit of said driving mechanism includes:
a fluid cylinder having a cylinder body connected pivotally to said base, and a piston rod coupled movably to said cylinder body and connected pivotally to said supporting unit;
a control switch mounted on said base and operable so as to output a control signal; and
a driving motor connected electrically to said control switch for driving said piston rod based on the control signal from said control switch to move and position said supporting unit to the desired position.

7. The elevating device as claimed in claim 1, wherein said cover unit includes:
a cover body having a front surface formed with a drawer-receiving groove; and
a drawer disposed movably in said drawer-receiving groove in said cover body.

8. The elevating device as claimed in claim 7, wherein:
said cover body of said cover unit has a top wall, a surrounding wall connected integrally to a periphery of said top wall, and an inner wall disposed parallel to and under said top wall and having a periphery that is connected integrally to said surrounding wall, said top wall cooperating with said inner wall and an upper portion of said surrounding wall of said cover body so as to define said drawer-receiving space; and
said base has a bottom wall, and a surrounding wall connected integrally to a peripheral portion of said bottom wall, said surrounding wall of said base having an annular outer surface in slidable contact with an annular inner surface of said surrounding wall of said cover body, said bottom wall and said surrounding wall of said base cooperating with said inner wall and a lower portion of said surrounding wall of said cover body so as to define said inner accommodating space.
